(19) United States
(12) Patent Application Publication
(10) Pub. No.: US 2025/0096809 A1
(43) Pub. Date: Mar. 20, 2025

(54) DELAY-LOCKED LOOP (DLL) WITH BINARY SEARCH LOCKING AND DEAD CLOCK DETECTION

(71) Applicant: Intel Corporation, Santa Clara, CA (US)

(72) Inventors: Nicolas Wainstein, Haifa (IL); Eugene Avner, Haifa (IL)

(21) Appl. No.: 18/370,480

(22) Filed: Sep. 20, 2023

(51) Int. Cl. H03L 7/10; H03L 7/081; H03L 7/089

(52) U.S. Cl. CPC H03L 7/105; H03L 7/0818; H03L 7/089

(57) ABSTRACT

A system includes memory and at least one processor coupled to the memory and configured to receive a phase detector (PD) error signal. The PD error signal indicates a leading clock signal of at least two clock signals. The at least two clock signals are generated based on an input clock signal and a voltage control signal. The at least one processor receives a toggling signal indicating whether one of the at least two clock signals is toggling between clock cycles of the input clock signal. A code value is generated based on the PD error signal and the toggling signal. The at least one processor causes generation of the voltage control signal based on the code value.

### BACKGROUND

Delay-locked loops (DLLs) are circuits specialized in generating one or multiple phases of a reference clock. The DLL is locked whenever the phase difference between the reference clock and the feedback clock is zero (or below the resolution of the phase detection circuit). The time required to lock the DLL is called locking time. In wireline communications, where the DLL is a fundamental part of the clocking system, its locking latency will be critical to the overall performance of the physical layer. Particularly, long locking times can cause large latencies during boot or when exiting idle or low power modes in several applications. Therefore, techniques to improve long locking times can be considered in connection with DLL circuit design and configuration.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1A illustrates a block diagram of a DLL architecture including loop control circuitry, in accordance with some embodiments;

FIG. 1B illustrates the DLL architecture of FIG. 1A with a more detailed view of the loop control circuitry, in accordance with some embodiments;

FIG. 1C is a diagram of a voltage-controlled delay line (VCDL) which can be used in connection with disclosed DLL architectures, in accordance with some embodiments;

FIG. 2A illustrates a graph of a simulation of a locking process in the DLL architecture of FIG. 1A using turbo mode for different PVT conditions at a low frequency (e.g., 800 MHZ), in accordance with some embodiments;

FIG. 2B illustrates a graph of a simulation of a locking process in the DLL architecture of FIG. 1A using turbo mode for different PVT conditions at a high frequency (e.g., 4.2 GHz), in accordance with some embodiments;

FIG. 3 illustrates a block diagram of a DLL architecture including a binary search controller and a toggle detection circuit, in accordance with some embodiments;

FIG. 4 is a flow diagram illustrating a finite state machine (FSM) of the binary search controller of FIG. 3, in accordance with some embodiments;

FIG. 5A illustrates a graph of simulation results of the binary search locking process in the DLL architecture of FIG. 3 for different PVT conditions at a low frequency (e.g., 2.1 GHZ), in accordance with some embodiments;

FIG. 5B illustrates a graph of simulation results of the binary search locking process in the DLL architecture of FIG. 3 for different PVT conditions at a high frequency (e.g., 4.2 GHz), in accordance with some embodiments;

FIG. 6 is a block diagram of the toggle detection circuit in the DLL architecture of FIG. 3, in accordance with some embodiments;

FIG. 7 is a graph of simulation results of the toggle detection circuit in the DLL architecture of FIG. 3, in accordance with some embodiments;

FIG. 8 is a flow diagram of an example method for generating a voltage control signal in a DLL architecture, in accordance with some embodiments; and

FIG. 9 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for, those of other embodiments. Embodiments outlined in the claims encompass all available equivalents of those claims.

As used herein, the term “chip” (or die) refers to a piece of a material, such as a semiconductor material, that includes a circuit such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

DLLs are circuits specialized in generating one or multiple phases of a reference clock. A DLL can use a phase detector (PD) (also referred to as a PD circuit) to lock the delay between the reference clock (also referred to as refclk) and the feedback clock (also referred to as fbclk) to a multiple of the reference clock cycle (typically one cycle). The DLL is locked whenever the phase difference between the reference clock and the feedback clock is zero (or below the resolution of the phase detection circuit).

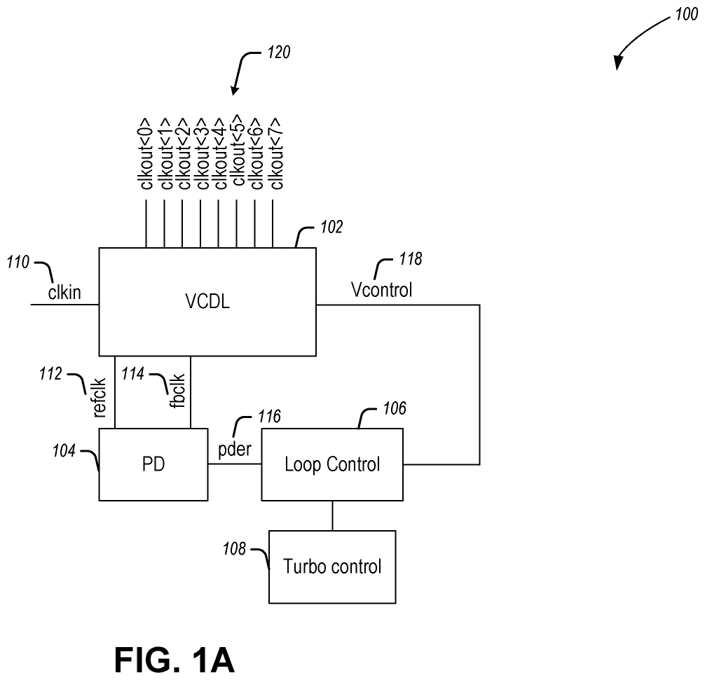

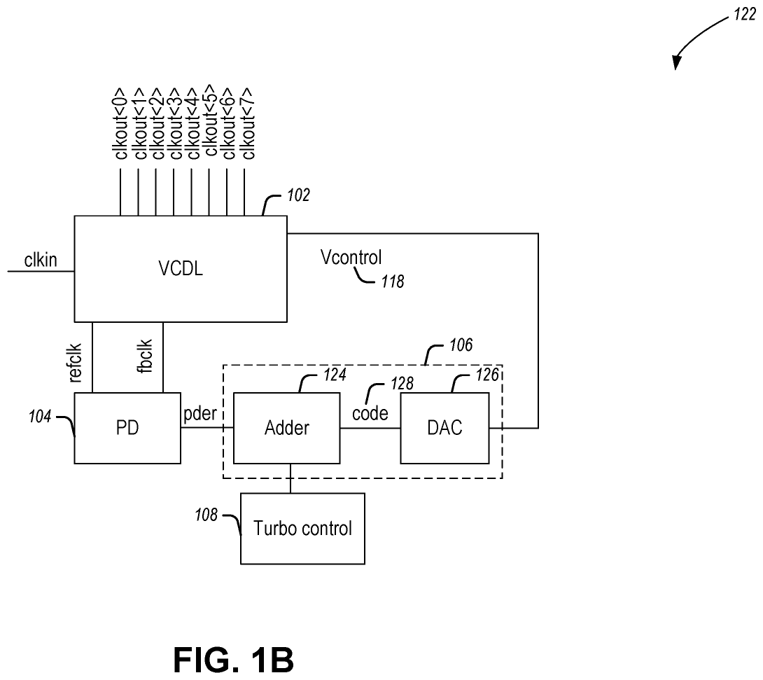

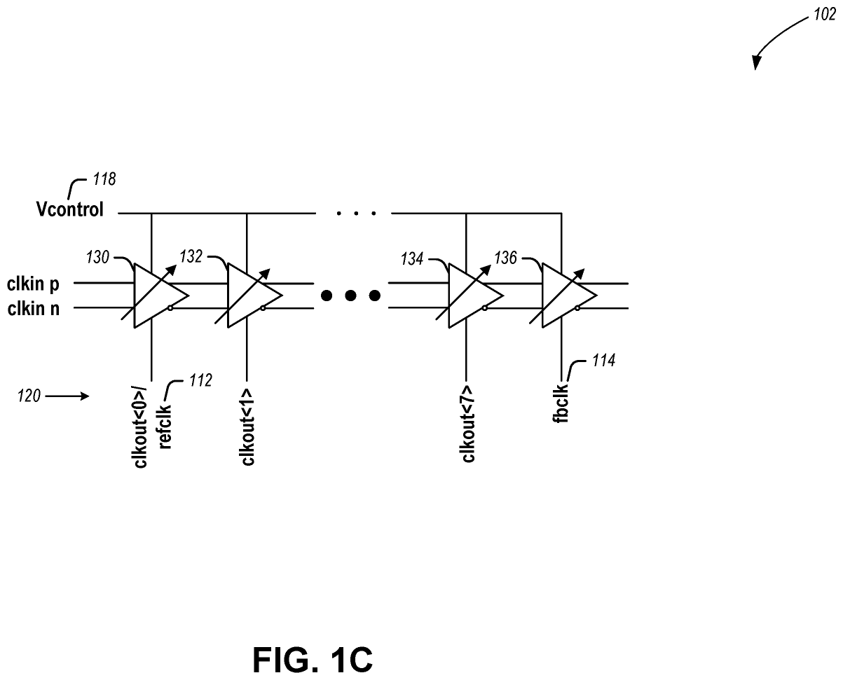

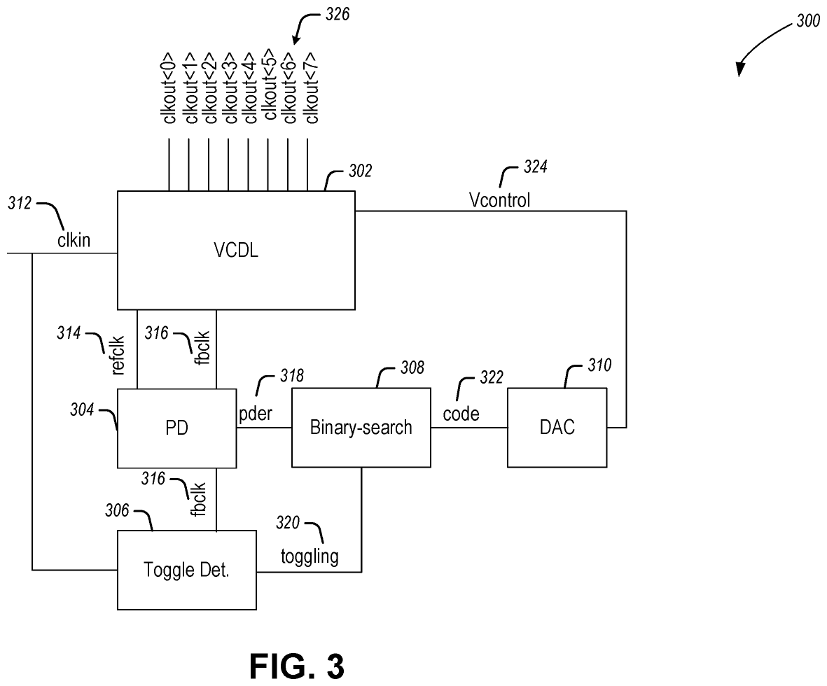

To guarantee that the delay is locked regardless of process, voltage, and temperature (PVT) variations, the delay is dynamically controlled by a voltage-controlled delay line (VCDL). In some aspects, VCDLs are implemented as a chain of delay elements (also referred to as delay stages) with varying load capacitance and/or varying effective driving strength. The delay elements (e.g., serially connected delay elements) generate phase-shifter clock output signals with a varying degree of phase shift. For example, as illustrated in FIG. 1A and FIG. 3, a set of eight delay stages is used to generate eight phase-shifted output clock signals with a phase shift varying from 0-315 degrees with a 45-degree phase shift difference between neighboring signals. A last (or ninth) delay stage can be used by the VCDL to generate the fbclk, where the last delay stage is configured with the same phase shift as the first delay stage (which generates refclk and the phase-shifted output clock with 0-degree phase shift). As used herein, refclk refers to the first clock output signal of a plurality of phase-shifted clock output signals generated by a DLL. In this regard, refclk can be a clock output signal with a zero-degree phase shift. As used herein, fbclk is the phase-shifted output clock signal generated by the last (ninth) delay stage that has the same (zero-degrees) phase shift as the first delay stage.

The driving strength is modulated either by changing the power supply or by using a current-starved topology which modulates the current of the inverter. In both options, usually, a digital-to-analog converter (DAC) (also referred to as a DAC circuit) or a charge pump controls the biasing of the delay element. The phase of the input and output (refclk and fbclk) clocks are compared using a PD circuit. The error signal (also referred to as PD error signal or pder) is fed back to a loop controller (or loop control circuit) that changes the DAC code in the required direction to force the error to zero (e.g., as illustrated in FIG. 1A and FIG. 1B).

The time required to lock the DLL is called locking time. In wireline communications, where the DLL is a fundamental part of the clocking system, its locking latency will be critical to the overall performance of the physical layer. Particularly, long locking times can cause large latencies during boot or when exiting idle or low power modes in several applications.

For high-performance applications, high-resolution bias control is required so that the delay can be tuned with picosecond resolution. This is reflected as an increment in the number of bits of the DAC or smaller capacitive ratios for charge pumps. Hence, the locking time is tightly related to the DLL resolution, and it increases as the number of bits in the DAC code increases. Furthermore, to prevent harmonic lock (i.e., locking at a wrong multiple of the desired delay between the output clock and the input clock), the starting condition of the DLL must guarantee that the feedback clock will be ahead of the reference clock at the input of the phase detector. This results in an inherent long locking time as usually the DAC must be initialized at code zero. Thus, the disclosed techniques can be used to improve (namely, reduce) the locking time of DLLs. With the disclosed DLL architecture, an improvement in the locking time is achieved.

In some aspects, DLL solutions can use a turbo mode (e.g., as illustrated in FIGS. 1A-1C) that changes the DAC code by larger steps (e.g., 40 instead of 1). Although the turbo mode improves the locking time, it can generate a condition where the clocks stop propagating through the VCDL due to large overshoots in the bias. This condition is called a “dead clock” and it requires to restart of the DLL initialization with other parameters such as capacitive bank configuration and driving strength of the delay stage in the VCDL. In some DLLs (and PHYs) this condition could be undetectable. The disclosed techniques provide an additional benefit in preventing the “dead clock” condition in DLL architectures.

In some aspects, DLL architectures can tackle the locking latency by using a turbo mode that increases the DAC code by larger steps to slow down the VCDL until the feedback lags the reference. After the first change in the phase detector output (the startup condition can guarantee that the feedback clock is ahead of the reference clock), the turbo mode is disabled, and the DAC will decrease the codes by a smaller step size (usually unitary steps).

A disadvantage of the turbo mode is the large overshoot, which might lead to the “dead clock” condition, namely, where the clock does not propagate through the VCDL because of a too-high (or too low in the case of NMOS) bias voltage, or due to a low power supply voltage. Another disadvantage of the turbo mode does not solve the latency issue completely since the step size is fixed (or can be chosen from a small set of values) which might be not suitable for all process-voltage-temperature (PVT) and frequency conditions and after a large overshoot, it will still take time to converge to the locking condition.

The disclosed techniques include a DLL architecture that uses a binary-search algorithm to lock (e.g., as discussed in connection with FIG. 3). Thus, the search is done in logarithmic time and can take log₂(B) steps, where B is the resolution of the DAC. To solve the issue associated with “dead clocks” owing to bias voltage overshoot, the disclosed DLL architecture can use a toggle detection circuit that feeds back the binary-search controller to return to the previous working value and continue the search with a smaller step.

The main advantage of the disclosed techniques is that they improve the locking time by 5-10× without sacrificing performance (i.e., keeping the same high precision and low phase error as with linear locking). The locking time can be reduced to 15 ns or less (compared to 150 ns in state-of-the-art implementations), which will allow subsystems (e.g., DDR PHY subsystems) to exit low power states faster, improving responsiveness and latency. Furthermore, the disclosed DLL architectures can reduce energy consumption as the overall transaction time can be reduced.

FIG. 1A illustrates a block diagram of a DLL architecture including loop control circuitry, in accordance with some embodiments. Referring to FIG. 1A, DLL 100 includes a VCDL circuit 102, a PD circuit 104, a loop control circuit 106, and a turbo control circuit 108.

VCDL circuit 102 is configured to generate a plurality of output clock signals 120 based on an input clock signal 110 and a voltage control signal 118. A more detailed diagram of VCDL circuit 102 is illustrated in FIG. 1C.

FIG. 1C is a diagram of a voltage-controlled delay line (VCDL) which can be used in connection with disclosed DLL architectures, in accordance with some embodiments. Referring to FIG. 1C, VCDL circuit 102 includes a plurality of delay stages 130, 132, . . . , 134, and 136. In some aspects, VCDL circuit 102 includes a total of nine delay stages generating output clock signals that are shifted by a pre-configured amount (e.g., by 45 degrees) from each other. In this regard, delay stage 130 has the same (zero degree) shift as delay stage 136. Delay stage 130 can be used to generate the reference clock signal 112 (or refclk signal 112), and delay stage 136 is used to generate the feedback clock signal 114 (or fbclk signal 114).

The VCDL circuit 102 includes delay stages 130, . . . , 136 that can tune their delay (e.g., using the voltage control signal 118).

The PD circuit 104 compares the phases of the reference clock signal 112 (refclk) against the feedback clock signal 114 (fbclk) and generates an output (e.g., PD error signal 116, or pder) indicating which of the clocks is leading. This output serves as the input of the loop control circuit 106, in charge of creating a bias or control voltage signal 118 (or Vcontrol) that modulates the delay of the VCDL circuit 102. The DLL 100 is locked whenever the phases of refclk and fbclk match (i.e., fall within the maximum resolution of the PD circuit).

FIG. 1B illustrates diagram 122 of the DLL architecture of FIG. 1A with a more detailed view of the loop control circuitry, in accordance with some embodiments. As illustrated in FIG. 1B, the loop control circuit 106 includes DAC circuit 126 and an adder 124 that controls the DAC code 128 depending on the value of the PD circuit 104 output. The DAC output (e.g., voltage control signal 118) is used as the bias of the VCDL (note that more than one bias can be used). One of the main purposes of DLLs is the generation of multiple phases of a reference clock. In the examples illustrated in FIGS. 1A-1C eight clock outputs are used (clkout<7:0>) (e.g., the plurality of output clock signals 120 are with different phases, such as phase shift of 0-315 degrees, with 45-degree increments).

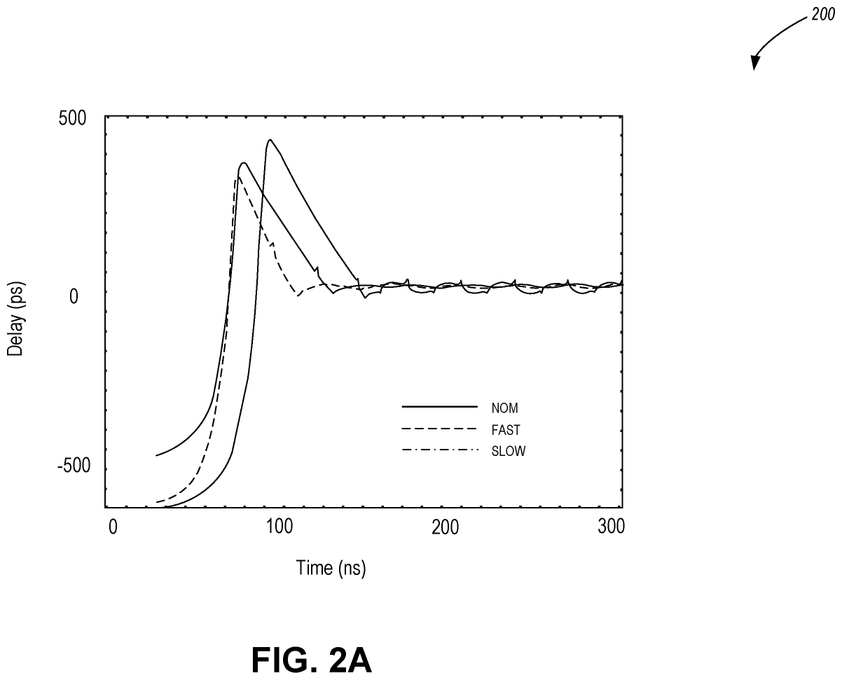

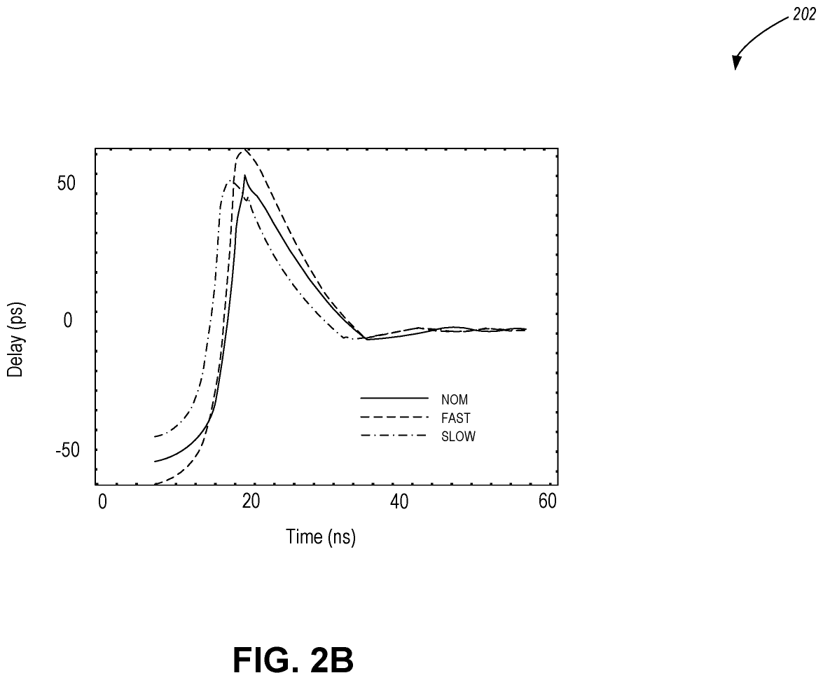

In some aspects, the turbo control circuit 108 is used to accelerate the locking phase. The turbo control circuit 108 changes the step size at which the DAC code is swept during startup or low-power mode exit and returns it to unit steps after the pder has changed its polarity. There can be a tight tradeoff between the turbo step and the bias overshoot. By increasing the turbo step, the locking time can be reduced. However, there is a large probability of code overshoot as shown in FIGS. 2A-2B, where the delay between refclk and fbclk is plotted against time for low and high frequencies, respectively.

FIG. 2A illustrates graph 200 of a simulation of a locking process in the DLL architecture of FIG. 1A using turbo mode for different PVT conditions at a low frequency (e.g., 800 MHZ), in accordance with some embodiments.

FIG. 2B illustrates graph 202 of a simulation of a locking process in the DLL architecture of FIG. 1A using turbo mode for different PVT conditions at a high frequency (e.g., 4.2 GHz), in accordance with some embodiments.

The DLL is locked whenever the delay between those clocks is 0 in a steady-state condition. Note that for low frequencies (2 GHZ) the locking process can last even more than 140 ns.

In some aspects, using turbo mode where the current code is one code before the locking condition (i.e., the DAC code that will be achieved in the steady-state locking condition), the turbo will cause the code to jump to a much higher code causing a large bias overshoot. The overshoot in the bias leads, in turn, to a delay overshoot as shown in FIGS. 2A-2B. More importantly, there will be a time penalty of n−1 clock cycles (where n is the turbo step size) until the DAC achieves the locking code. Even more problematic, the code overshoot can lead to a very large bias voltage that creates a “dead clock” condition, namely a condition where the clock does not propagate through the VCDL because of a too high (or too low in the case of NMOS) bias voltage, or due to a low power supply voltage. This issue requires a complete reset of the DLL and a rerun of the startup with a lower turbo step size.

To cope with the long locking times and the dead clocks, the disclosed techniques can include a DLL architecture that uses a binary-search controller to control the DAC that creates the bias voltage. A toggle detection circuit senses fbclk to check that the clock is toggling and that the large changes in the bias voltage at the beginning of the binary search did not lead to a “dead clock” condition. In the event of a dead clock, the toggling detector raises a flag (‘toggling’) to the binary-search controller. This DLL architecture is depicted in FIG. 3 (the clock controlling the binary search controller is not shown in the figure, which clock can be generated by a configurable clock divider).

FIG. 3 illustrates a block diagram of a DLL architecture including a binary search controller and a toggle detection circuit, in accordance with some embodiments. Referring to FIG. 3, DLL 300 includes a VCDL circuit 302, a PD circuit 304, a binary search controller circuit 308 (also referred to as a controller circuit 308), a DAC circuit 310, and a toggle detection circuit 306.

VCDL circuit 302 is configured to generate a plurality of output clock signals 326 based on an input clock signal 312 and a voltage control signal 324. A more detailed diagram of VCDL circuit 302 is illustrated in FIG. 1C.

In some aspects, VCDL circuit 302 includes a plurality of delay stages which generate the plurality of output clock signals 326. For example, about FIG. 1C, VCDL circuit 302 includes delay stages 130, . . . , 136. In some aspects, delay stages 130, . . . , 136 can include a total of nine delay stages with the first delay stage 130 generating output clock signal clkout<0> (which can be the same as refclk signal 314) and the last delay stage 136 (e.g., the ninth delay stage that has the same zero-degree phase shift as the first delay stage 130) generating the fbclk signal 316. The reference signal (refclk) and the feedback signal (fbclk) are generated based on the input clock signal 312 and the voltage control signal 324.

The output signals of the VCDL circuit 302 (e.g., refclk signal 314 and fbclk signal 316) are communicated to the PD circuit 304. The PD circuit 304 generates the PD error signal 318 (also referred to as pder signal 318) based on the refclk signal 314 and the fbclk signal 316. More specifically, pder signal 318 indicates which one of the two clock signals is leading. For example, pder=1 when the fbclk signal 316 is leading and pder=0 when the refclk signal 314 is leading.

The fbclk signal 316 and the input clock signal 312 are also communicated to the toggle detection circuit 306 and are used for generating the toggling signal 320. In some aspects, the toggling signal 320 indicates whether the fbclk signal 316 toggles between clock cycles of the input clock signal 312 (e.g., toggling signal 320 can be asserted as high (or logical 1) when there is toggling of the fbclk signal 316 and low (or logical 0) when there is no toggling of the fbclk signal 316.

The toggling signal 320 and the PD error signal 318 are communicated to the binary search controller circuit 308 which is configured to perform a binary search to obtain a DAC code 322. The DAC code 322 is communicated to the DAC circuit 310, which uses the DAC code 322 to generate the voltage control signal 324.

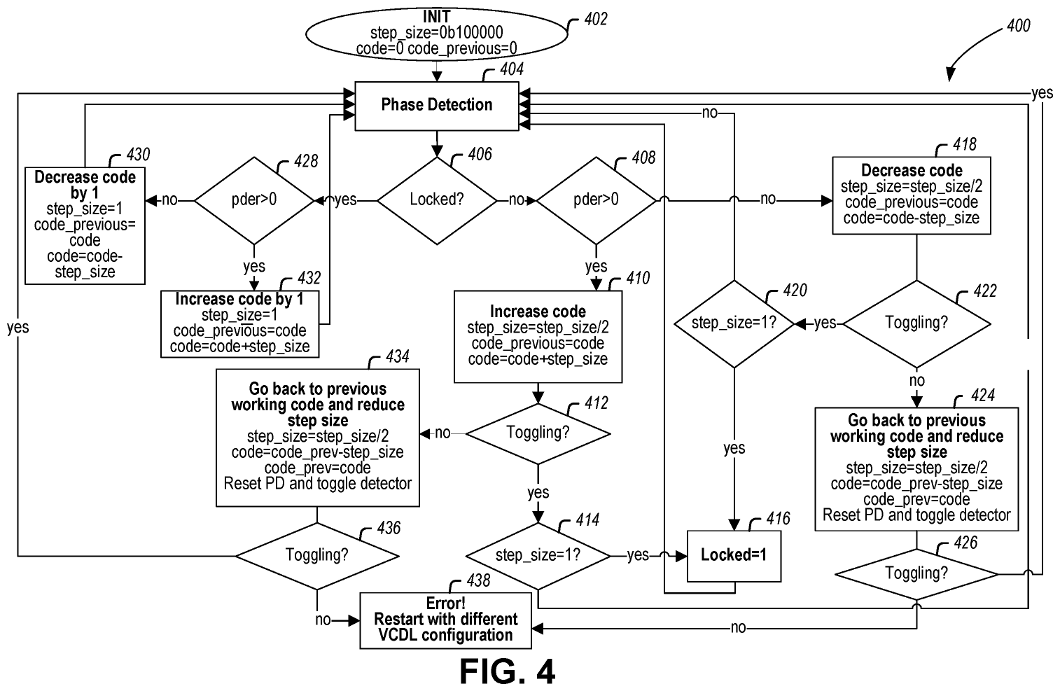

FIG. 4 is a flow diagram illustrating a finite state machine 400 of the binary search controller of FIG. 3, in accordance with some embodiments. Referring to FIG. 4, finite state machine 400 of the binary search controller circuit 308 is initialized at operation 402 with a step size of 0b100000 (or half the step size range) and an initial DAC code of 0. At operation 404, phase detection is performed.

At operation 406, it is determined whether the VCDL circuit is locked.

If not locked, at operation 408, it is determined whether pder>0 (e.g., whether fbclk is leading).

If pder>0, at operation 410, the code is increased (e.g., the step size is reduced in half, and the code is incremented by the new step size).

At operation 412, a determination is made on whether there is toggling (e.g., toggling signal 320 indicates that fbclk signal 316 is toggling). If there is toggling, at operation 414 it is determined whether the step size is 1. If it is 1, at operation 416, the VCDL is considered locked and the operation continues to phase detection at operation 404. If at operation 414 step size is not 1, the operation continues to phase detection at operation 404.

If at operation 412 there is no toggling, at operation 434, the controller circuit goes back to the previous working code, and the step size is reduced in half. At operation 436, a determination on toggling is made. If there is no toggling, at operation 438, an error is assumed and a restart is performed with a different VCDL configuration.

If there is toggling at operation 436, the operation continues to phase detection at operation 404.

If pder is not greater than zero at operation 408, processing continues at operation 418 when the code is decreased (e.g., the step size is reduced in half and the code is reduced by the new step size). At operation 422, a determination of toggling is made. If there is no toggling, at operation 424, the controller circuit can go back to using the previous working code, and the step size is reduced.

At operation 426 toggling determination is made. If there is toggling, the operation continues to phase detection at operation 404. If there is no toggling at operation 426, at operation 438, an error is assumed and a restart is performed with a different VCDL configuration.

If there is toggling at operation 422, a determination is made at operation 420 on whether the step size is 1. If it is not 1, the operation continues to phase detection at operation 404. If it is 1, the VCDL is considered locked and the operation continues to phase detection at operation 404.

If at operation 406 it is determined the VCDL circuit is locked, at operation 428 it is determined whether pder>0. If pder is not greater than zero, at operation 430 the code is decreased by 1 and the operation continues to phase detection at operation 404. If pder>0, at operation 432 the code is increased by 1 and the operation continues to phase detection at operation 404.

Referring to FIG. 3 and FIG. 4, instead of performing a linear search, the binary search can start at code zero to prevent harmonic lock and then it can jump directly to the middle range code. Then, depending on the polarity of the PD error signal (pder), the controller circuit can continue searching with a step size of a quarter of the range. The binary search will continue dividing the step size by two until the step size of one is achieved. The division by two in the digital domain only requires shifting right the binary code. At that point, the step size reaches one, and the DLL will be locked. Thus, in a scenario where there are no dead clocks, the locking condition will be achieved in log₂(B) steps, where B is the number of bits in the DAC code. The locking time is then T_{ctrl}×log₂(B), where T_{ctrl} is the cycle time of the binary search controller clock.

If at any time the toggle detection circuit senses a “dead clock” condition, the binary search controller will go back to the previous code, change the step size to half of the previous size, and reset the PD circuit performing the phase detection. In other words, in the event of a dead clock, the binary search will skip a step size and continue with the next step size. The finite state machine (FSM) of the controller circuit 308 is shown in FIG. 4 and explained above. The step is initialized at the middle range code value and the previous code is always stored in the event of undesired “dead clocks”. The logic ‘1’ in the step is shifted right (>>) at each iteration until a step of size one is reached.

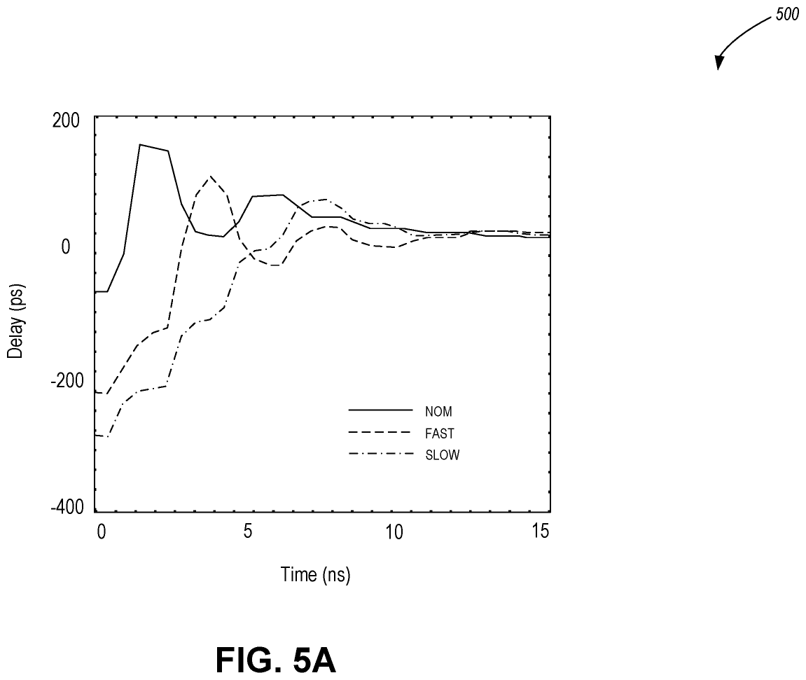

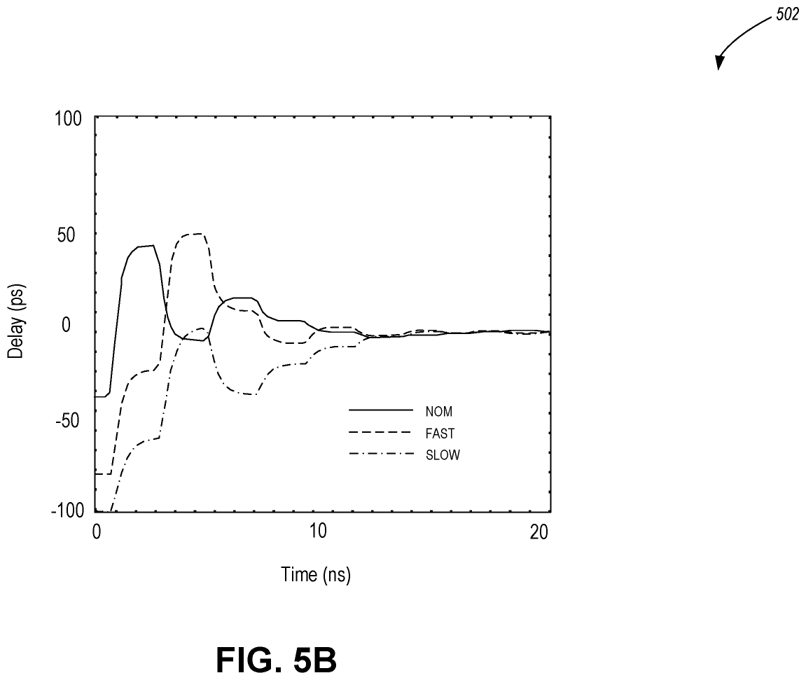

Examples of the locking process in the disclosed DLL architecture of FIG. 3 are shown in FIG. 5A and FIG. 5B for low (2 GHZ) and high (4 GHZ) frequencies, respectively.

FIG. 5A illustrates a graph 500 of simulation results of the binary search locking process in the DLL architecture of FIG. 3 for different PVT conditions at a low frequency (e.g., 2.1 GHZ), in accordance with some embodiments.

FIG. 5B illustrates graph 502 of simulation results of the binary search locking process in the DLL architecture of FIG. 3 for different PVT conditions at a high frequency (e.g., 4.2 GHz), in accordance with some embodiments.

It can be observed in FIGS. 5A-5B that the DLL architecture of FIG. 3 achieves the locking condition in less than 12 ns for both low and high frequencies. This is an improvement of 5-10 times in the locking time over existing DLL technologies. The static phase error and dithering (dynamic ripple of the delay) are not affected by the new binary search controller.

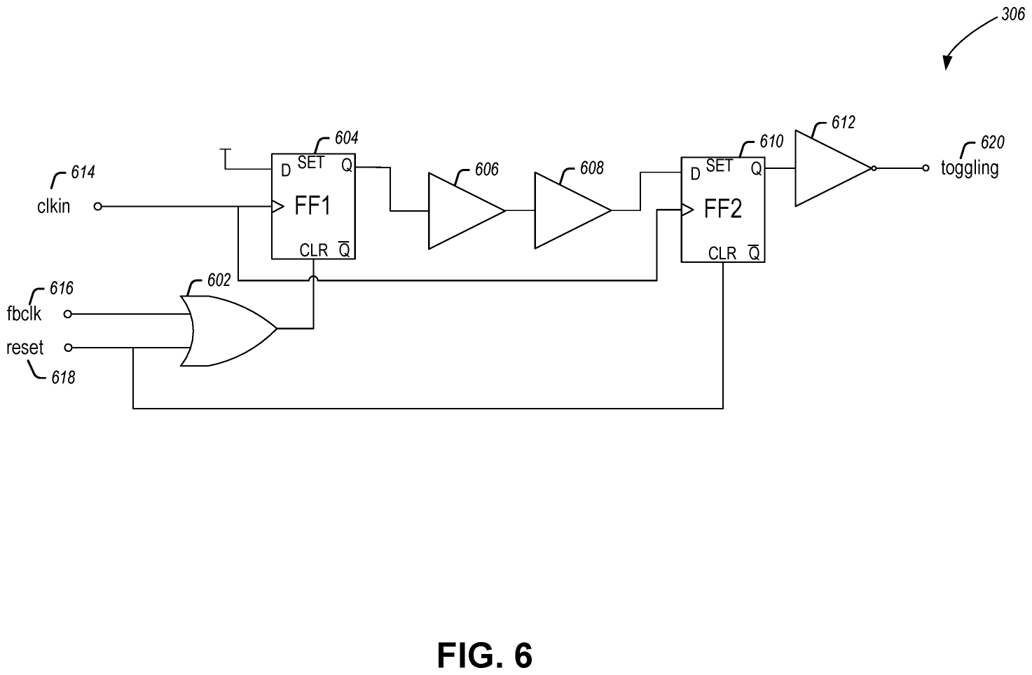

FIG. 6 is a block diagram of the toggle detection circuit 306 in the DLL architecture of FIG. 3, in accordance with some embodiments. Referring to FIG. 6, the toggle detection circuit can include flip-flop circuits 604 and 610, an OR gate 602, buffers 606 and 608, and an inverter 612. The fbclk signal 616 and a reset signal 618 are communicated as inputs to the OR gate 602. The input clock signal 614 and an output of the OR gate 602 are communicated as inputs to the flip-flop circuit 604. The reset signal 618, the input clock signal 614, and the output of buffer 608 are communicated as inputs to the flip-flop circuit 610. The inverter 612 receives as input the output signal of flip-flop circuit 610. The toggling signal 620 (which is the same as the toggling signal 320) is generated as output of the inverter 612.

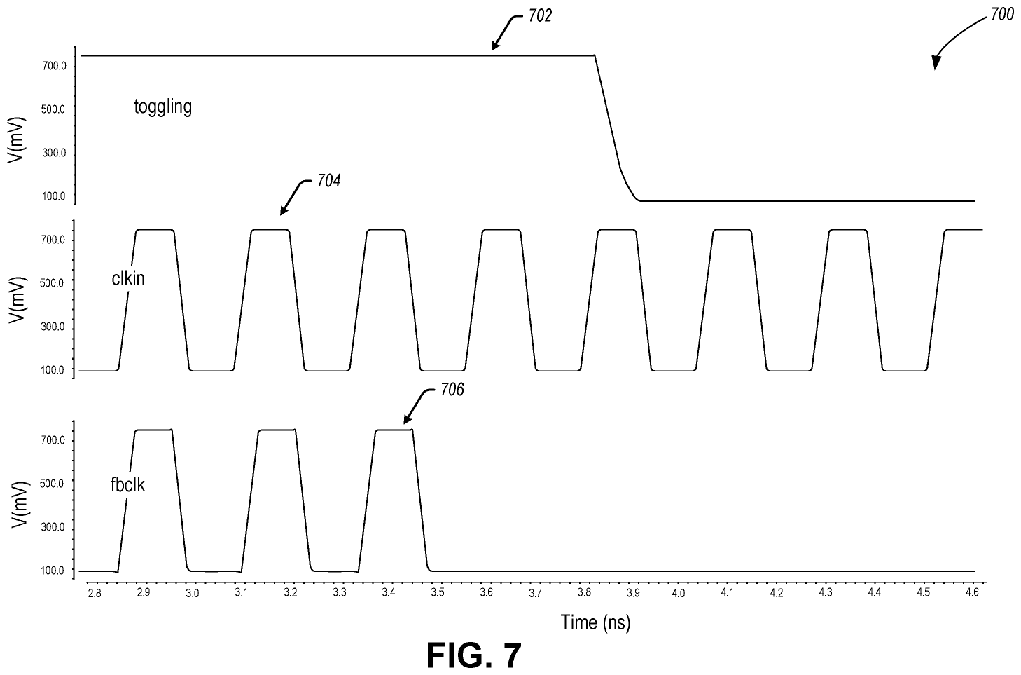

The toggle detection circuit 306 works as follows. First, both flip-flop circuits (FFs) are reset. As the input clock signal 614 (clkin) starts toggling, FF1 will sample a constant ‘1’ at the rising edge of clkin. The phase between clkin and fbclk varies according to the VCDL, but it falls between −180° to 180°. Hence, FF1 will be cleared before FF2 samples a ‘1’. This will keep the output toggling fixed at logic ‘1’. However, in the event of a “dead clock” condition, fbclk will stop toggling and will be stuck at logic ‘0’. In this case, logic ‘1’ will propagate and it will be sampled by FF2, changing the output to logic ‘0’. This block can use other clock inputs if other clock outputs of the DLL must be monitored. An example of the toggling detector waveforms is depicted in FIG. 7. In some aspects, extra delay elements can be added to the toggling detector circuit to fix the timing between the clocks according to the VCDL implementation.

FIG. 7 is graph 700 of the simulation results of the toggle detection circuit in the DLL architecture of FIG. 3, in accordance with some embodiments. Graph 700 includes graph 702 illustrating the toggling signal, graph 704 illustrating the input clock signal 614, and graph 706 illustrating the fbclk signal 616.

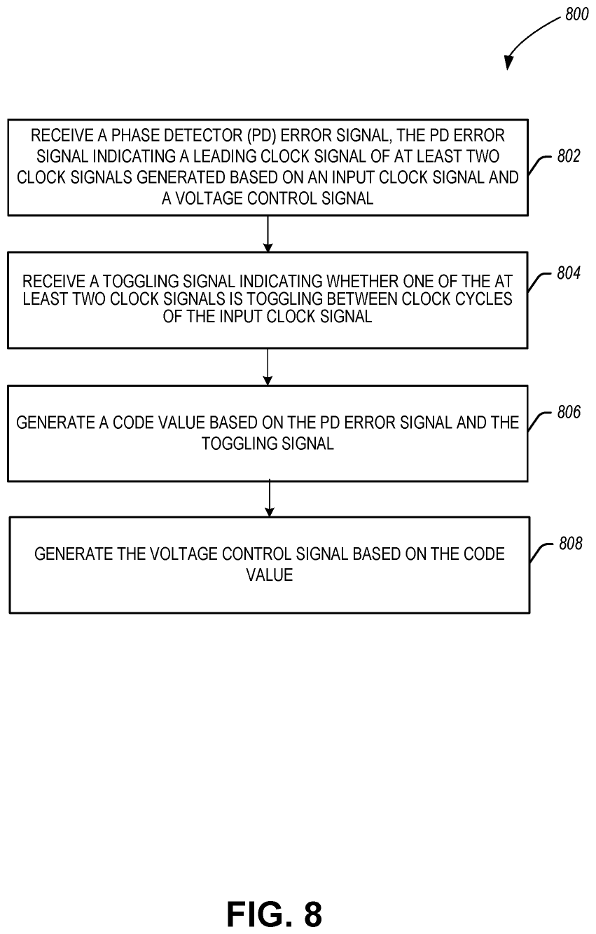

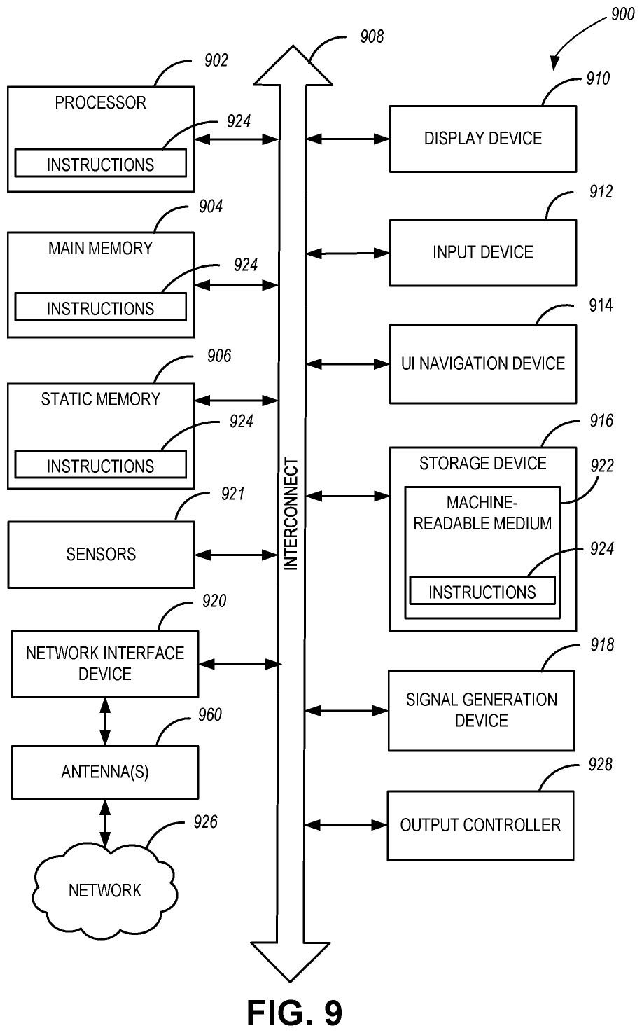

FIG. 8 is a flow diagram of an example method 800 for generating a voltage control signal in a DLL architecture, in accordance with some embodiments. Referring to FIG. 8, method 800 includes operations 802, 804, 806, and 808, which may be executed by a clock management circuit or another processor of a computing device (e.g., hardware processor 902 of machine 900 illustrated in FIG. 9 which can include one or more of the circuits of DLL 300). In some embodiments, one or more of the circuits of the DLL 300 can perform the functionalities discussed in FIG. 8 as well as in the examples listed below.

At operation 802, a phase detector (PD) error signal is received. For example, PD error signal 318 is received by the controller circuit 308. The PD error signal indicates a leading clock signal of at least two clock signals (e.g., refclk signal 314 and fbclk signal 316). The at least two clock signals are generated based on an input clock signal (e.g., input clock signal 312) and a voltage control signal (e.g., voltage control signal 324).

At operation 804, a toggling signal is received. For example, controller circuit 308 receives toggling signal 320 from the toggle detection circuit 306. The toggling signal indicates whether one of the at least two clock signals (e.g., fbclk signal 316) is toggling between the clock cycles of the input clock signal (e.g., input clock signal 312).

At operation 806, a code value is generated based on the PD error signal and the toggling signal. For example, controller circuit 308 generates DAC code 322 communicated to DAC circuit 310.

At operation 808, the voltage control signal is generated based on the code value. For example, DAC circuit 310 generates the voltage control signal 324 based on the DAC code 322.

FIG. 9 illustrates a block diagram of an example machine 900 upon which any one or more of the techniques (e.g., methodologies) discussed herein may perform. In alternative embodiments, the machine 900 may operate as a standalone device or may be connected (e.g., networked) to other machines. In a networked deployment, machine 900 may operate in the capacity of a server machine, a client machine, or both in server-client network environments. In an example, machine 900 may function as a peer machine in a peer-to-peer (P2P) (or other distributed) network environment. The machine 900 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 900 may include a hardware processor 902 (e.g., a central processing unit (CPU), a graphics processing unit (GPU), a hardware processor core, or any combination thereof), a main memory 904, and a static memory 906, some or all of which may communicate with each other via an interlink (e.g., bus) 908. In some aspects, the main memory 904, the static memory 906, or any other type of memory (including cache memory) used by machine 900 can be configured based on the disclosed techniques or can implement the disclosed memory devices.

Specific examples of main memory 904 include Random Access Memory (RAM), and semiconductor memory devices, which may include, in some embodiments, storage locations in semiconductors such as registers. Specific examples of static memory 906 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 900 may further include a display device 910, an input device 912 (e.g., a keyboard), and a user interface (UI) navigation device 914 (e.g., a mouse). In an example, the display device 910, input device 912, and UI navigation device 914 may be a touch screen display. The machine 900 may additionally include a storage device (e.g., drive unit or another mass storage device) 916, a signal generation device 918 (e.g., a speaker), a network interface device 920, and one or more sensors 921, such as a global positioning system (GPS) sensor, compass, accelerometer, or other sensors. The machine 900 may include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 902 and/or instructions 924 may comprise processing circuitry and/or transceiver circuitry.

The storage device 916 may include a machine-readable medium 922 on which one or more sets of data structures or instructions 924 (e.g., software) embodying or utilized by any one or more of the techniques or functions described herein can be stored. Instructions 924 may also reside, completely or at least partially, within the main memory 904, within static memory 906, or the hardware processor 902 during execution thereof by the machine 900. In an example, one or any combination of the hardware processor 902, the main memory 904, the static memory 906, or the storage device 916 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 922 is illustrated as a single medium, the term “machine-readable medium” may include a single medium or multiple media (e.g., a centralized or distributed database, and/or associated caches and servers) configured to store instructions 924.

An apparatus of the machine 900 may be one or more of a hardware processor 902 (e.g., a central processing unit (CPU), a graphics processing unit (GPU), a hardware processor core, or any combination thereof), a main memory 904 and a static memory 906, one or more sensors 921, a network interface device 920, one or more antennas 960, a display device 910, an input device 912, a UI navigation device 914, a storage device 916, instructions 924, a signal generation device 918, and an output controller 928. The apparatus may be configured to perform one or more of the methods and/or operations disclosed herein. The apparatus may be intended as a component of machine 900 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 900 and that causes machine 900 to perform any one or more of the techniques of the present disclosure, or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 924 may further be transmitted or received over a communications network 926 using a transmission medium via the network interface device 920 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 920 may include one or more physical jacks (e.g., Ethernet, coaxial, or phone jacks) or one or more antennas to connect to the communications network 926. In an example, the network interface device 920 may include one or more antennas 960 to wirelessly communicate using at least one single-input multiple-output (SIMO), multiple-input multiple-output (MIMO), or multiple-input single-output (MISO) techniques. In some examples, the network interface device 920 may wirelessly communicate using Multiple User MIMO techniques. The term “transmission medium” shall be taken to include any intangible medium that can store, encode, or carry instructions for execution by the machine 900, and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a certain manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments such as part of a system on chip, a set of intercommunicating functional blocks, or similar, although the scope of the disclosure is not limited in this respect.

Described implementations of the subject matter can include one or more features, alone or in combination as illustrated below by way of examples.

Example 1 is an apparatus comprising: a voltage-controlled delay line (VCDL) circuit comprising a plurality of delay stages associated with a corresponding plurality of phase delay values, the plurality of delay stages generating a plurality of output clock signals based on an input clock signal and a voltage control signal; a phase detector (PD) circuit coupled to output terminals of at least two delay stages of the plurality of delay stages, the PD circuit to receive at least two clock signals of the plurality of output clock signals via the output terminals of the at least two delay stages, and to generate a PD error signal based on the at least two clock signals; and a controller circuit comprising: a first input terminal coupled to an output terminal of the PD circuit to receive the PD error signal; a second input terminal to receive a toggling signal associated with one of the at least two clock signals; and an output terminal to output a code value based on the PD error signal and the toggling signal, the voltage control signal based on the code value.

In Example 2, the subject matter of Example 1 includes, wherein the plurality of delay stages are serially coupled to each other.

In Example 3, the subject matter of Examples 1-2 includes, wherein each phase delay value of the plurality of phase delay values indicates a phase offset between two output clock signals of the plurality of output clock signals generated by neighboring delay stages of the plurality of delay stages.

In Example 4, the subject matter of Examples 1-3 includes, wherein a phase difference between the at least two clock signals generated by the at least two delay stages is zero degrees.

In Example 5, the subject matter of Example 4 includes, wherein the PD circuit generates the PD error signal to indicate a leading clock signal of the at least two clock signals.

In Example 6, the subject matter of Examples 1-5 includes, wherein the at least two clock signals comprise a first clock signal generated by a first delay stage of the at least two delay stages, and wherein the first delay stage receives the input clock signal.

In Example 7, the subject matter of Example 6 includes, wherein the at least two clock signals comprise a second clock signal generated by a second delay stage of the at least two delay stages, and wherein a phase difference between the first clock signal and the second clock signal is zero degrees.

In Example 8, the subject matter of Example 7 includes, wherein the second delay stage is communicatively coupled to the first delay stage via at least a third delay stage of the plurality of delay stages.

In Example 9, the subject matter of Examples 7-8 includes, wherein the PD error signal is a logical one when the second clock signal leads the first clock signal, and wherein the PD error signal is a logical zero when the first clock signal leads the second clock signal.

In Example 10, the subject matter of Examples 1-9 includes a digital-to-analog converter (DAC) circuit comprising an input terminal coupled to the output terminal of the controller circuit, wherein the DAC circuit generates the voltage control signal based on the code value.

In Example 11, the subject matter of Examples 1-10 includes a toggle detection circuit comprising: a first input terminal to receive the input clock signal; a second input terminal to receive one of the at least two clock signals received by the PD circuit; and an output terminal to the second input terminal of the controller circuit, the output terminal to output the toggling signal to the controller circuit.

In Example 12, the subject matter of Example 11 includes, wherein the at least two clock signals comprise a first clock signal and a second clock signal, wherein the first clock signal is generated by a first delay stage of the at least two delay stages, wherein the first delay stage receives the input clock signal, wherein the second clock signal is generated by a second delay stage of the at least two delay stages, and wherein a phase difference between the first clock signal and the second clock signal is zero degrees.

In Example 13, the subject matter of Example 12 includes, wherein the second input terminal of the toggle detection circuit receives the second clock signal.

In Example 14, the subject matter of Example 13 includes, wherein the toggling signal is asserted when the second clock signal is toggling between clock cycles of the input clock signal, and wherein the toggling signal is de-asserted when the second input signal is not toggling between the clock cycles of the input clock signal.

In Example 15, the subject matter of Examples 11-14 includes, wherein the toggle detection circuit further comprises: a first flip-flop circuit coupled to the first input terminal of the toggle detection circuit; an OR gate coupled to the second input terminal of the toggle detection circuit; and one or more buffers coupled to an output of the first flip-flop circuit.

In Example 16, the subject matter of Example 15 includes, wherein the toggle detection circuit further comprises: a second flip-flop circuit coupled to the one or more buffers; and an inverter circuit coupled to an output of the second flip-flop circuit.

In Example 17, the subject matter of Example 16 includes, wherein the OR gate and the second flip-flop circuit receive a reset signal, the first flip-flop circuit is coupled to an output of the OR gate, and the inverter circuit outputs the toggling signal.

In Example 18, the subject matter of Examples 1-17 includes, one or more interconnects coupled to the plurality of output clock signals of the VCDL circuit.

In Example 19, the subject matter of Examples 1-18 includes, wherein the apparatus comprises a processor, and wherein the processor includes one or more of the VCDL circuit, the PD circuit, and the controller circuit.

In Example 20, the subject matter of Example 19 includes, one or more interconnects coupling the VCDL circuit, the PD circuit, and the controller circuit.

Example 21 is a system comprising: memory; and at least one processor coupled to the memory, the at least one processor receives a phase detector (PD) error signal, the PD error signal indicating a leading clock signal of at least two clock signals, the at least two clock signals generated based on an input clock signal and a voltage control signal; receive a toggling signal, the toggling signal indicating whether one of the at least two clock signals is toggling between clock cycles of the input clock signal; generate a code value based on the PD error signal and the toggling signal; and cause generation of the voltage control signal based on the code value.

In Example 22, the subject matter of Example 21 includes, a digital-to-analog converter (DAC) circuit coupled to the at least one processor, and wherein the at least one processor is further to supply the code value to the DAC circuit.

In Example 23, the subject matter of Example 22 includes, wherein the DAC circuit is to: generate a voltage control signal based on the code value.

In Example 24, the subject matter of Example 23 includes a voltage-controlled delay line (VCDL) circuit with a plurality of delay stages associated with a corresponding plurality of phase delay values.

In Example 25, the subject matter of Example 24 includes, wherein the plurality of delay stages are to: generate a plurality of output clock signals based on the input clock signal and the voltage control signal, the plurality of output clock signals comprising the at least two clock signals.

In Example 26, the subject matter of Example 25 includes, wherein the at least two clock signals comprise a first clock signal generated by a first delay stage of the plurality of delay stages, and wherein the first delay stage receives the input clock signal.

In Example 27, the subject matter of Example 26 includes, wherein the at least two clock signals comprise a second clock signal generated by a second delay stage of the plurality of delay stages, and wherein a phase difference between the first delay stage and the second delay stage is zero degrees.

In Example 28, the subject matter of Example 27 includes, a phase detector (PD) circuit coupled to output terminals of at least two delay stages of the plurality of delay stages.

In Example 29, the subject matter of Example 28 includes, wherein the PD circuit is to: receive the at least two clock signals of the plurality of output clock signals via the output terminals of the at least two delay stages; and generate the PD error signal based on the at least two clock signals.

In Example 30, the subject matter of Example 29 includes, a toggle detection circuit, wherein the toggle detection circuit is to: receive the input clock signal; receive the second clock signals received by the PD circuit; and generate the toggling signal to indicate whether the second clock signals is toggling between the clock cycles of the input clock signal.

In Example 31, the subject matter of Example 30 includes, wherein the at least one processor comprises one or more of the DAC circuit, the VCDL circuit, the PD circuit, and the toggling circuit.

In Example 32, the subject matter of Example 31 includes, one or more interconnects coupling the DAC circuit, the VCDL circuit, the PD circuit, and the toggling circuit.

In Example 33, the subject matter of Examples 22-32 includes, wherein the at least one processor is further to initialize generating the code value based on an initial code value of zero and an initial step size equal to half a code range associated with the DAC circuit.

In Example 34, the subject matter of Example 33 includes, wherein the at least one processor is further to: perform one or more successive reductions of the initial step size based on dividing a current step size in half; and perform one or more successive increases in the code value based on the current step size.

In Example 35, the subject matter of Example 34 includes, wherein the at least one processor is further to: detect a locking condition when the current step size equals one and the toggling signal indicates the one of the at least two clock signals is toggling between the clock cycles of the input clock signal.

In Example 36, the subject matter of Example 35 includes, wherein the at least one processor is further to output the code value based on detecting the locking condition.

Example 37 is a method comprising: receiving a phase detector (PD) error signal, the PD error signal indicating a leading clock signal of at least two clock signals, the at least two clock signals generated based on an input clock signal, and a voltage control signal; receiving a toggling signal, the toggling signal indicating whether one of the at least two clock signals is toggling between clock cycles of the input clock signal; generating a code value based on the PD error signal and the toggling signal; and generating the voltage control signal based on the code value.

In Example 38, the subject matter of Example 37 includes, generating a plurality of output clock signals based on the input clock signal and the voltage control signal, the plurality of output clock signals comprising the at least two clock signals.

In Example 39, the subject matter of Example 38 includes, wherein the at least two clock signals comprise a first clock signal generated by a first delay stage of a plurality of delay stages, and wherein the first delay stage receives the input clock signal.

In Example 40, the subject matter of Example 39 includes, wherein the at least two clock signals comprise a second clock signal generated by a second delay stage of the plurality of delay stages, and wherein a phase difference between the first delay stage and the second delay stage is zero degrees.

In Example 41, the subject matter of Example 40 includes, generating the toggling signal to indicate whether the second clock signal is toggling between the clock cycles of the input clock signal.

In Example 42, the subject matter of Examples 37-41 includes, initializing generating the code value based on an initial code value of zero and an initial step size equal to half a code range associated with a digital-to-analog converter (DAC) circuit.

In Example 43, the subject matter of Example 42 includes, performing one or more successive reductions of the initial step size based on dividing a current step size in half; and performing one or more successive increases in the code value based on the current step size.

In Example 44, the subject matter of Example 43 includes, detecting a locking condition when the current step size equals one and the toggling signal indicates the one of the at least two clock signals is toggling between the clock cycles of the input clock signal.

In Example 45, the subject matter of Example 44 includes, outputting the code value based on detecting the locking condition.

Example 46 is an apparatus comprising means to perform a method as described in any preceding claim.

Example 47 is machine-readable storage including machine-readable instructions, when executed, cause a transceiver to implement a method as described in any preceding claim.

Example 48 is machine-readable storage including machine-readable instructions, when executed, cause an equalization circuit to implement a method as described in any preceding claim.

Example 49 is a computer program comprising instructions which, when the program is executed by a computer, cause the computer to carry out the method as described in any preceding claim.

Example 50 is at least one machine-readable medium including instructions that, when executed by processing circuitry, cause the processing circuitry to perform operations to implement any of Examples 1-49.

Example 51 is an apparatus comprising means to implement any of Examples 1-49.

Example 52 is a system to implement any of Examples 1-49.

Example 53 is a method to implement any of Examples 1-49.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a voltage-controlled delay line (VCDL) circuit to generate a plurality of output clock signals based on an input clock signal and a voltage control signal;
a phase detector (PD) circuit to generate a PD error signal; and
a controller circuit to receive the PD error signal and a toggling signal and to output a code value based on the PD error signal and the toggling signal.

2. The apparatus of claim 1, wherein the VCDL circuit comprises a plurality of delay stages associated with a corresponding plurality of phase delay values, the plurality of delay stages generating the plurality of output clock signals based on the input clock signal and the voltage control signal.

3. The apparatus of claim 2, wherein the PD circuit is coupled to output terminals of at least two delay stages of the plurality of delay stages, the PD circuit to receive at least two clock signals of the plurality of output clock signals via the output terminals of the at least two delay stages, and to generate the PD error signal based on the at least two clock signals.

4. The apparatus of claim 3, wherein the controller circuit comprises:
a first input terminal coupled to an output terminal of the PD circuit to receive the PD error signal;
a second input terminal to receive a toggling signal associated with one of the at least two clock signals; and
an output terminal to output a code value based on the PD error signal and the toggling signal, the voltage control signal based on the code value.

5. The apparatus of claim 4, wherein a phase difference between the at least two clock signals generated by the at least two delay stages is zero degrees, and wherein the PD circuit generates the PD error signal to indicate a leading clock signal of the at least two clock signals.

6. The apparatus of claim 4, wherein the at least two clock signals comprise a first clock signal generated by a first delay stage of the at least two delay stages, wherein the first delay stage receives the input clock signal, wherein the at least two clock signals comprise a second clock signal generated by a second delay stage of the at least two delay stages, wherein a phase difference between the first clock signal and the second clock signal is zero degrees, and wherein the second delay stage is communicatively coupled to the first delay stage via at least a third delay stage of the plurality of delay stages.

7. The apparatus of claim 4, further comprising:
a digital-to-analog converter (DAC) circuit comprising an input terminal coupled to the output terminal of the controller circuit, wherein the DAC circuit is to generate the voltage control signal based on the code value.

8. The apparatus of claim 4, further comprising:
a toggle detection circuit comprising:
a first input terminal to receive the input clock signal;
a second input terminal to receive one of the at least two clock signals received by the PD circuit; and
an output terminal to the second input terminal of the controller circuit, the output terminal to output the toggling signal to the controller circuit.

9. The apparatus of claim 8, wherein the at least two clock signals comprise a first clock signal and a second clock signal, wherein the first clock signal is generated by a first delay stage of the at least two delay stages, wherein the first delay stage receives the input clock signal, wherein the second clock signal is generated by a second delay stage of the at least two delay stages, and wherein a phase difference between the first clock signal and the second clock signal is zero degrees.

10. The apparatus of claim 8, wherein the toggle detection circuit further comprises:
a first flip-flop circuit coupled to the first input terminal of the toggle detection circuit;
an OR gate coupled to the second input terminal of the toggle detection circuit; and
one or more buffers coupled to an output of the first flip-flop circuit.

11. The apparatus of claim 10, wherein the toggle detection circuit further comprises:
a second flip-flop circuit coupled to the one or more buffers; and
an inverter circuit coupled to an output of the second flip-flop circuit.

12. The apparatus of claim 11, wherein the OR gate and the second flip-flop circuit receive a reset signal, the first flip-flop circuit is coupled to an output of the OR gate, and the inverter circuit outputs the toggling signal.

13. The apparatus of claim 4, further comprising:
one or more interconnects coupled to the plurality of output clock signals of the VCDL circuit.

14. A system comprising:
memory; and
at least one processor coupled to the memory, the at least one processor to:
receive a phase detector (PD) error signal, the PD error signal indicating a leading clock signal of at least two clock signals, the at least two clock signals generated based on an input clock signal and a voltage control signal;
receive a toggling signal, the toggling signal indicating whether one of the at least two clock signals is toggling between clock cycles of the input clock signal;
generate a code value based on the PD error signal and the toggling signal; and
cause generation of the voltage control signal based on the code value.

15. The system of claim 14, further comprising a digital-to-analog converter (DAC) circuit coupled to the at least one processor, and wherein the at least one processor is further to:
supply the code value to the DAC circuit.

16. The system of claim 15, wherein the DAC circuit is to:
generate a voltage control signal based on the code value.

17. The system of claim 16, further comprising a voltage-controlled delay line (VCDL) circuit with a plurality of delay stages associated with a corresponding plurality of phase delay values.

18. A method comprising:
receiving a phase detector (PD) error signal, the PD error signal indicating a leading clock signal of at least two clock signals, the at least two clock signals generated based on an input clock signal and a voltage control signal;
receiving a toggling signal, the toggling signal indicating whether one of the at least two clock signals is toggling between clock cycles of the input clock signal;
generating a code value based on the PD error signal and the toggling signal; and
generating the voltage control signal based on the code value.

19. The method of claim 18, further comprising:
initializing generating the code value based on an initial code value of zero and an initial step size equal to half a code range associated with a digital-to-analog converter (DAC) circuit.

20. The method of claim 19, further comprising:
performing one or more successive reductions of the initial step size based on dividing a current step size in half; and
performing one or more successive increases in the code value based on the current step size.
